(19) United States
(12) Patent Application Publication
(10) Pub. No.: US 2026/0291088 A1
(43) Pub. Date: Sep. 24, 2026

(54) ELECTRICAL CONNECTION COMPONENT AND ELECTRICAL CONNECTION UNIT

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Yasuhiro KUDO, Mie (JP); Daisuke HASHIMOTO, Mie (JP); Kentaro TACHI, Mie (JP); Yoshitomo TSUJII, Mie (JP)

(21) Appl. No.: 19/476,170

(22) PCT Filed: Apr. 3, 2024
(86) PCT No.: PCT/JP2024/013850

§ 371 Date: Oct. 17, 2025

(30) Foreign Application Priority Data
Apr. 21, 2023 (JP) 2023-070228

(51) Int. Cl. H01R 9/24

(52) U.S. Cl. CPC H01R 9/24; H01R 2201/10

(57) ABSTRACT

An electrical connection component includes a wiring and a body portion integrally provided to the wiring. The body portion is fixed to an enclosure as a mounting destination by fastening portions. The body portion includes mounting portions including holes, through which shaft portions of the fastening portions are passed. At least one of the mounting portions doubles as a positioning portion for the enclosure and the body portion.

### TECHNICAL FIELD

The present disclosure relates to an electrical connection component and an electrical connection unit.

### BACKGROUND

Conventionally, a terminal block for rotating electric machine includes a power connector, a signal connector and a base portion insert-molded with a collar in a molten resin as disclosed in Patent Document 1. The terminal block for rotating electric machine is positioned by fitting a positioning pin provided on the base portion into a case when being fixed to the case. The base portion is fixed to the case by a screw.

### PRIOR ART DOCUMENT

### Patent Document Patent Document 1: JP 2011-160619 A

### SUMMARY OF THE INVENTION

### Problems to be Solved

In the case of the terminal block for rotating electric machine disclosed in Patent Document 1, the base portion needs to be formed with the positioning pin. Thus, there has been a concern that the base portion and, consequently, the terminal block for rotating electric machine are enlarged accordingly.

The present disclosure aims to provide an electrical connection component and an electrical connection unit reducible in size.

### Means to Solve the Problem

An electrical connection component for solving the above problem is provided with a wiring and a body portion integrally provided to the wiring, the body portion being fixed to an enclosure as a mounting destination by fastening portions, the body portion including mounting portions provided with holes, shaft portions of the fastening portions being passed through the holes, and at least one of the mounting portions doubling as a positioning portion for the enclosure and the body portion.

### Effect of the Invention

The present disclosure can reduce a size of an electrical connection component.

### BRIEF DESCRIPTION OF THE DRAWINGS

FIG. 1 is a perspective view of the external appearance of an electrical connection unit according to a first embodiment.

FIG. 2 is a perspective view of an electrical connection component when viewed from a back side.

FIG. 3 is an exploded perspective view of the electrical connection unit.

FIG. 4 is a section along IV-IV shown in FIG. 1.

FIG. 5 is a section enlargedly showing a part of the electrical connection unit.

FIGS. 6A to 6D are diagrams showing a procedure of a drawing process.

FIG. 7 is a perspective view showing the external appearance of an enclosure according to a second embodiment.

FIG. 8 is a section enlargedly showing a part of an electrical connection unit.

FIG. 9 is a perspective view of an electrical connection component according to a third embodiment when viewed from a back side.

FIG. 10 is a vertical section of the electrical connection unit.

FIG. 11 is a section enlargedly showing a part of the electrical connection unit.

FIG. 12 is a diagram summarizing the mounting of a crimp collar.

FIG. 13 is a perspective view of an electrical connection component according to a fourth embodiment when viewed from a back side.

FIG. 14 is a vertical section of the electrical connection unit.

FIG. 15 is a section enlargedly showing a part of the electrical connection unit.

FIG. 16 is a section enlargedly showing a part of an electrical connection unit of another example.

### DETAILED DESCRIPTION TO EXECUTE THE INVENTION

First, embodiments of the present disclosure are listed and described.
[1] The electrical connection component of the present disclosure is provided with a wiring and a body portion integrally provided to the wiring, the body portion being fixed to an enclosure as a mounting destination by fastening portions, the body portion including mounting portions provided with holes, shaft portions of the fastening portions being passed through the holes, and at least one of the mounting portions doubling as a positioning portion for the enclosure and the body portion.

According to this configuration, in the electrical connection component to be mounted on the enclosure by the fastening portions, the mounting portion for mounting the fastening portion doubles as the positioning portion for the electrical connection component and the enclosure. Thus, it is not necessary to separately provide the mounting portions and the positioning portion. Therefore, the electrical connection component can be reduced in size.
[2] In [1] described above, the body portion includes an insulating portion for insulating between a plurality of the wirings and a plate portion integrally provided to the insulating portion, the plate portion being fixed to the enclosure by the fastening portions, and at least one of the mounting portions is provided in the plate portion. According to this configuration, since the plate portion is a thin member, this further contributes to the size reduction of the electrical connection component.
[3] In [2] described above, at least one of the mounting portions is integrally formed to the plate portion. According to this configuration, the number of components can be reduced as compared to the case where the mounting portions are configured separately from the plate portion.
[4] In [3] described above, the mounting portion includes a drawn portion having a projecting wall projecting toward the enclosure from a peripheral edge of the hole. According to this configuration, the mounting portions can be easily integrally formed to the plate portion by a drawing process.
[5] In [1] described above, at least one of the mounting portions includes a separate component independent of the body portion. According to this configuration, manufacturing variations of the mounting portion can be increased, using the separate component.
[6] In [5] described above, the body portion includes an insulating portion for insulating between a plurality of the wirings and a plate portion integrally provided to the insulating portion, the plate portion being fixed to the enclosure by the fastening portions, the separate component is a collar to be mounted in the plate portion while including a collar hole communicating with a plate hole formed in the plate portion, and at least one of the mounting portions includes the plate hole and the collar. According to this configuration, the mounting portion can be easily formed, using a general-purpose collar.
[7] In [5] described above, the body portion is an insulating resin for insulating between a plurality of the wirings, and at least one of the mounting portions is constituted by an insert collar as the separate component insert-molded in the insulating resin. According to this configuration, the electrical connection component can be manufactured by a simple method of insert-molding the wiring and the insert collar with the resin.

[8] In any one of [1] to [7] described above, the enclosure includes an engaging portion to be engaged with the mounting portion, and the engaging portion includes a projection-like portion projecting from a surface of the enclosure and positions the electrical connection component and the enclosure while the projection-like portion is engaged with the mounting portion. According to this configuration, the enclosure and the electrical connection component are engaged by causing the projection-like portion as the engaging portion to project from the enclosure to the electrical connection component. Thus, for example, if the mounting portions have a projecting shape, it is not necessary to increase a projecting amount thereof. This further contributes to the size reduction of the electrical connection component.

[9] In any one of [1] to [7] described above, the enclosure includes an engaging portion to be engaged with the mounting portion, and the engaging portion includes a recess-like portion recessed from a surface of the enclosure and positions the electrical connection component and the enclosure while the mounting portion is accommodated in the recess-like portion. According to this configuration, if the enclosure is provided with the engaging portion, it is sufficient to recess a part of the surface of the enclosure by a simple processing. This contributes to the simple manufacturing of the enclosure.

[10] An electrical connection unit of the present disclosure is provided with an electrical connection component including a wiring and a body portion integrally provided to the wiring, and an enclosure, the electrical connection component being fixed to the enclosure by fastening portions, the body portion including mounting portions provided with holes, shaft portions of the fastening portions being passed through the holes, and at least one of the mounting portions doubling as a positioning portion for the enclosure and the body portion. According to this configuration, functions and effects similar to those of the electrical connection component can be obtained.

### DETAILS OF EMBODIMENTS OF PRESENT DISCLOSURE

### First Embodiment

A specific example of the present disclosure is described below with reference to the drawings. Note that the present invention is not limited to these illustrations, but is represented by claims and intended to include all changes in the scope of claims and in the meaning and scope of equivalents. For the convenience of description, some components may be shown in an exaggerated or simplified manner in each drawing. Further, a dimension ratio of each part may be different from an actual one.

### Electrical Connection Unit 1

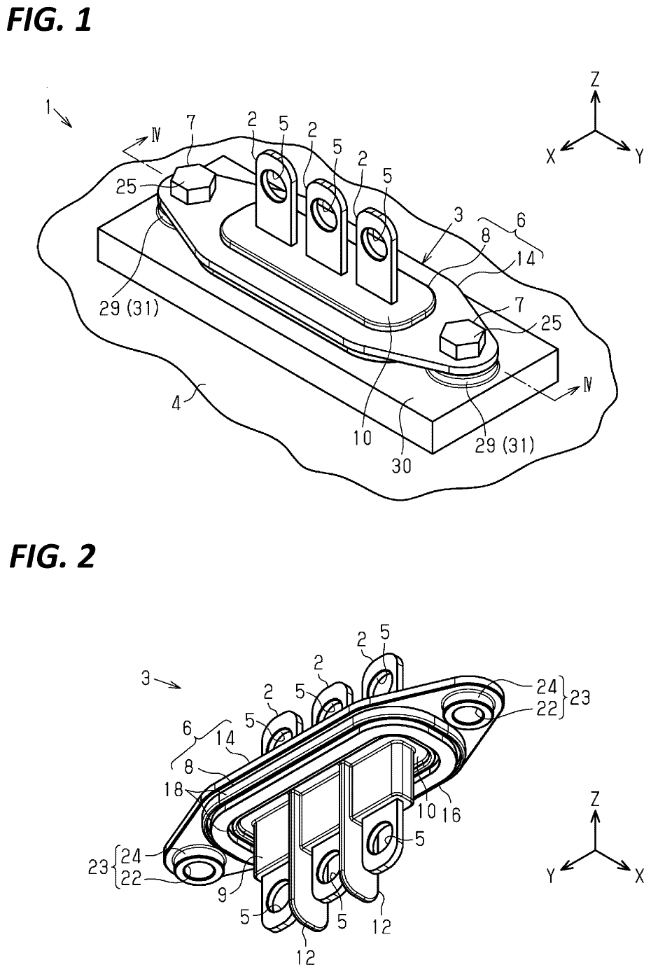

As shown in FIG. 1, an electrical connection unit 1 is provided with an electrical connection component 3 including wirings 2 and an enclosure 4 as a mounting destination of the electrical connection component 3. The electrical connection component 3 is, for example, a terminal block for fixing and mounting mating wirings (not shown) to the wirings 2 by bolts or the like. The wiring 2 is, for example, a bar-like conductor, i.e. a so-called busbar, in which a large current flows. The electrical connection unit 1 is, for example, a terminal block unit.

### Electrical Connection Component 3

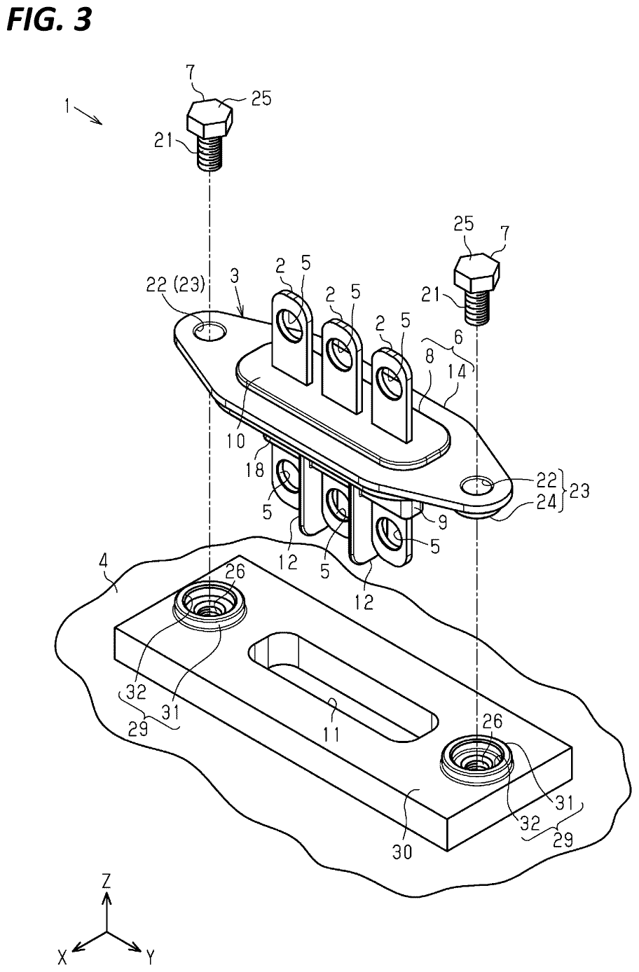

As shown in FIGS. 2 and 3, a plurality of the wirings 2 are provided side by side in a width direction of the electrical connection component 3 (Y-axis direction in FIG. 2 and the like). In the case of this example, the plurality of wirings 2 are arranged at equal intervals in the width direction of the electrical connection component 3 (Y-axis direction of FIG. 2 and the like). The wiring 2 is, for example, a busbar made of metal. Insertion holes 5, through which members such as bolts for fixing the mating wirings (not shown) are inserted, are formed in both ends of the wiring 2.

For example, the electrical connection component 3 electrically connects a motor (not shown) installed inside the enclosure 4 and an external inverter (not shown). The motor is, for example, a three-phase alternating current motor. In this case, three wirings 2 constitute a U-phase, a V-phase and a W-phase. Alternating current signals having phases different from each other by 120° are, for example, caused to flow in the respective wirings 2 of the U-, V- and W-phases. A high voltage and a large current signal necessary for the three-phase alternating current motor flow in each wiring 2.

The electrical connection component 3 is provided with a body portion 6 integrally provided with the wirings 2. The body portion 6 of the electrical connection component 3 is fixed to the enclosure 4 as the mounting destination by fastening portions 7 (see FIG. 3 and the like). The fastening portions 7 are, for example, bolts. In the case of this example, the body portion 6 is fixed to the enclosure 4 by a plurality of (two in this example) fastening portions 7.

The body portion 6 includes an insulating portion 8 for insulating the plurality of provided wirings 2. A resin is, for example, used as a material of the insulating portion 8. The insulating portion 8 includes a wiring supporting portion 9 for supporting the wirings 2 and a flange portion 10 extending in a direction intersecting the wiring supporting portion 9. The wiring supporting portion 9 is provided on the back surface of the flange portion 10 and arranged in an opening hole 11 (see FIG. 3) of the enclosure 4 when the electrical connection component 3 is mounted on the enclosure 4. A plurality of wall portions 12 for insulating the wirings 2 adjacent to each other stand on the wiring supporting portion 9.

The body portion 6 is provided with a plate portion 14 made of metal and used when the electrical connection component 3 is mounted on the enclosure 4. The plate portion 14 is integrally provided to the insulating portion 8 and fixed to the enclosure 4 as the mounting destination by the fastening portions 7. The plate portion 14 is, for example, insert-molded together with the wirings 2, thereby being integrally formed to the wirings 2 and the insulating portion 8. The plate portion 14 is, for example, formed into a substantially long plate shape having substantially tapered both ends. A metal material such as iron is, for example, used as a material of the plate portion 14.

As shown in FIG. 2, the electrical connection component 3 includes a sealing member 16 for sealing a gap between the electrical connection component 3 and the enclosure 4. The sealing member 16 is, for example, formed into an annular shape. The sealing member 16 is, for example, a rubber packing. An acrylic material, a silicon material or the like is, for example, used as a material of the sealing member 16. The sealing member 16 is pressed by a seal supporting portion 17 provided on the insulating portion 8 for supporting the sealing member 16. The seal supporting portion 17 is, for example, annularly formed on the back surface of the flange portion 10 to surround the wiring supporting portion 9. The seal supporting portion 17 includes a pair of positioning walls 18 on both sides of the sealing member 16.

An assembly including the wirings 2, the insulating portion 8 and the plate portion 14 is, for example, formed by insert molding. Specifically, the wirings 2 and the plate portion 14 are set in a mold, and the integrated assembly of the wirings 2, the insulating portion 8 and the plate portion 14 is manufactured by insert molding of filling a resin into the mold. In this way, the plate portion 14 is integrally formed to the insulating portion 8 by insert molding.

### Fixing Structure of Electrical Connection Component 3 and Enclosure 4

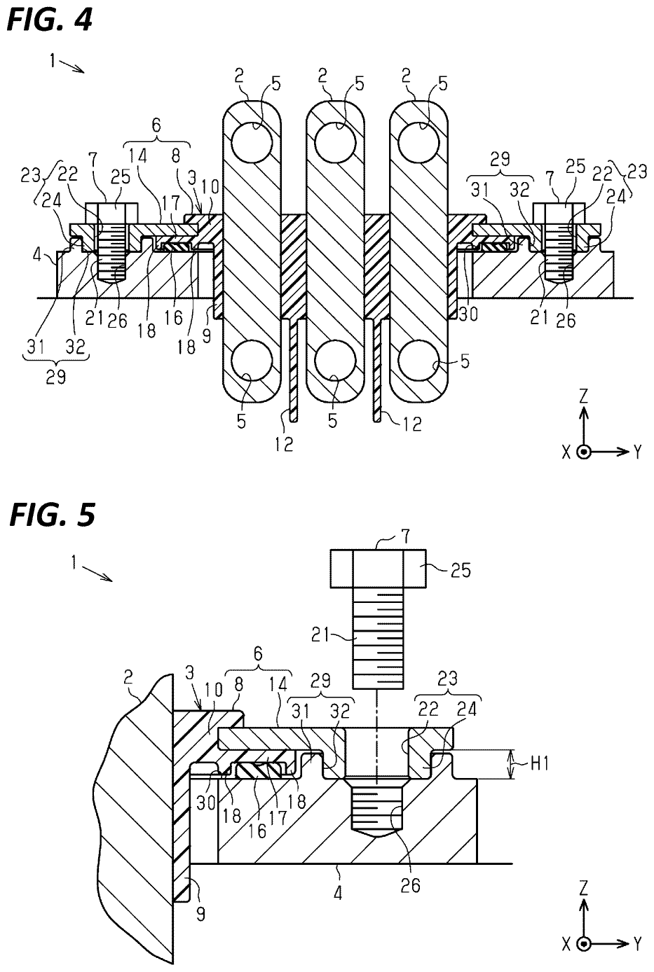

As shown in FIGS. 3 and 4, the body portion 6 includes mounting portions 23 provided with holes 22, through which shaft portions 21 of the fastening portions 7 are passed. In the case of this example, at least one of the mounting portions 23 is provided in the plate portion 14. Specifically, at least one of the mounting portions 23 is integrally formed in the plate portion 14. The mounting portions 23 are provided on both sides of the plate portion 14. As just described, in the case of this example, the plate portion 14 includes a total of two mounting portions 23 respectively arranged on both sides in the width direction of the plate portion 14 (Y-axis direction of FIG. 3 and the like).

As shown in FIGS. 4 and 5, the mounting portion 23 includes a drawn portion having a projecting wall 24 projecting toward the enclosure 4 from the peripheral edge of the hole 22. In this way, the mounting portion 23 is formed by a drawing process. The mounting portion 23 includes the hole 22 described above and the projecting wall 24. The inner peripheral surface of the hole 22 is formed into a smooth shape without any screw threads. As just described, the inner peripheral surface of the hole 22 is a flat surface without any irregularities. The fastening portion 7 fixes the plate portion 14 to the enclosure 4 by fastening the shaft portion 21 to a fastened portion 26 recessed in the enclosure 4 while bringing a head portion 25 into contact with the upper surface of the mounting portion 23.

### Positioning Structure of Electrical Connection Component 3 and Enclosure 4

As shown in FIGS. 3 and 4, the enclosure 4 includes engaging portions 29 to be engaged with the mounting portions 23. In the case of this example, the engaging portion 29 includes a projection-like portion 31 projecting from a surface 30 of the enclosure 4. The engaging portions 29 are provided on both sides of the enclosure 4, whereby a total of two engaging portions 29 are formed. The engaging portion 29 is formed into a circumferential shape (in this example, a true circular shape) in a plan view. The engaging portion 29 includes a recess 32 inside the projection-like portion 31. The fastened portion 26 is recessed in the bottom surface of the recess 32 and arranged in a center of the recess 32.

As shown in FIG. 5, the engaging portion 29 positions the electrical connection component 3 and the enclosure 4 by engaging the mounting portion 23 with the projection-like portion 31. As just described, at least one of the mounting portions 23 of this example doubles as a positioning portion for the enclosure 4 and the body portion 6. In the case of this example, the mounting portion 23 is engaged inside the projection-like portion 31. That is, the mounting portion 23 is fit into the projection-like portion 31 when the electrical connection component 3 is mounted on the enclosure 4. A height H1 of the projecting wall 24 is set to a value, which is the sum of a thickness of the seal supporting portion 17 supported by the plate portion 14 and a thickness of the sealing member 16 resiliently deformed by being pressed by the seal supporting portion 17.

Next, functions of this embodiment are described.

### Procedure of Drawing Process

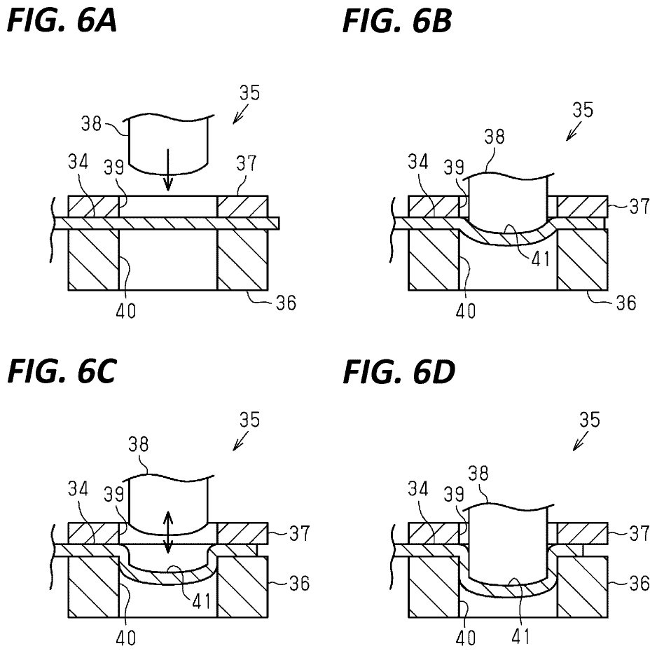

As shown in FIG. 6A, a base material (hereinafter, referred to as a plate base material 34) of the plate portion 14 is first set in a drawing machine 35 to form the mounting portion 23 in the plate portion 14. Specifically, the plate base material 34 is placed on a base portion 36 of the drawing machine 35 and the upper surface of the plate base material 34 is pressed by a pressing portion 37 of the drawing machine 35. The pressing portion 37 includes an opening 39, through which a punch 38 for striking the plate base material 34 passes. The base portion 36 includes a guide recess 40 for guiding the deformation of the plate base material 34 when the plate base material 34 is struck by the punch 38.

As shown in FIG. 6B, the drawing machine 35 strikes the plate base material 34 by the punch 38. At this time, a recess 41 is formed in the plate base material 34 by a pressing force load of the punch 38. Further, if the recess 41 is formed in the plate base material 34 by the punch 38, an end part of the plate base material 34 is pulled and moved toward the recess 41. At this time, the plate base material 34 is forcibly pulled by the punch 38, whereby an annular pattern is engraved over an entire circumference at the position of the plate base material 34 corresponding to a corner of the base portion 36.

Then, as shown in FIG. 6C, the punch 38 repeatedly strikes the recess 41 until the recess 41 reaches a necessary depth. At this time, a hitting force of the recess 41 and a hitting number per unit time by the punch 38 are not necessarily constant regardless of a deformation amount of the recess 41. For example, to obtain a desired depth of the recess 41, the hitting force of the recess 41 and the hitting number per unit time by the punch 38 may be changed as appropriate.

As shown in FIG. 6D, if the depth of the recess 41 reaches the necessary depth, striking by the punch 38 is finished. Then, the plate base material 34 is removed from the drawing machine 35 and the bottom wall of the recess 41 is cut by a jig (not shown) to form a hole in the recess 41. In this way, the mounting portion 23 including the hole 22 and the projecting wall 24 is formed. Similarly, a similar drawing process is applied also to the opposite side of the plate base material 34, whereby the mounting portion 23 is formed. In the above way, the mounting portions 23 are formed on both sides of the plate base material 34.

### Positioning of Electrical Connection Component 3 With Respect to Enclosure 4

As shown in FIG. 3, when the electrical connection component 3 is fixed to the enclosure 4, the wiring supporting portion 9 of the electrical connection component 3 is inserted into the opening hole 11 of the enclosure 4 and the projecting walls 24 of the mounting portions 23 formed in the electrical connection component 3 are fit into the recesses 32 of the engaging portions 29 formed in the enclosure 4. Then, the shaft portions 21 of the fastening portions 7 are inserted into the holes 22 of the mounting portions 23 and fastened to the fastened portions 26 in the recesses 32, whereby the electrical connection component 3 is fixed to the enclosure 4. In the case of this example, the electrical connection component 3 is fixed to the enclosure 4 by two fastening portions 7.

As just described, when the electrical connection component 3 is fixed to the enclosure 4, the projecting walls 24 of the electrical connection component 3 are fit into the recesses 32 of the enclosure 4, whereby the electrical connection component 3 is positioned with respect to the enclosure 4. That is, the mounting portions 23, through which the fastening portions 7 are passed, are also used to position the electrical connection component 3 with respect to the enclosure 4. Thus, it is not necessary to provide a positioning portion separately from the mounting portions 23. Therefore, the electrical connection component 3 and, consequently, the electrical connection unit 1 can be reduced in size.

### Effects of First Embodiment

According to the electrical connection component 3 (electrical connection unit 1) of the first embodiment, the following effects can be obtained.
(1.1) The electrical connection component 3 is provided with the body portion 6 integrally provided to the wirings 2, and the body portion 6 is fixed to the enclosure 4 as the mounting destination by the fastening portions 7. The body portion 6 includes the mounting portions 23 provided with the holes 22, through which the shaft portions 21 of the fastening portions 7 are passed. At least one of the mounting portions 23 doubles as the positioning portion for the enclosure 4 and the body portion 6.

According to this configuration, in the electrical connection component 3 to be mounted on the enclosure 4 by the fastening portions 7, the mounting portion 23 for mounting the fastening portion 7 doubles as the positioning portion for the electrical connection component 3 and the enclosure 4. Thus, it is not necessary to provide the positioning portion separately from the mounting portions 23. Therefore, the electrical connection component 3 can be reduced in size.
(1.2) The body portion 6 includes the insulating portion 8 for insulating between the plurality of wirings 2 and the plate portion 14 integrally provided to the insulating portion 8 and to be fixed to the enclosure 4 by the fastening portions 7. At least one of the mounting portions 23 is provided in the plate portion 14. According to this configuration, since the plate portion 14 is a thin member, it further contributes to the size reduction of the electrical connection component 3.
(1.3) At least one of the mounting portions 23 is integrally formed to the plate portion 14. According to this configuration, the number of components can be reduced as compared to the case where the mounting portion 23 is configured separately from the plate portion 14.
(1.4) The mounting portion 23 includes the drawn portion having the projecting wall 24 projecting toward the enclosure 4 from the peripheral edge of the hole 22. According to this configuration, the mounting portion 23 can be easily integrally formed to the plate portion 14 by the drawing process.
(1.5) The enclosure 4 includes the engaging portions 29 to be engaged with the mounting portions 23. The engaging portion 29 includes the projection-like portion 31 projecting from the surface 30 of the enclosure 4, and the projection-like portion 31 positions the electrical connection component 3 and the enclosure 4 while being engaged with the mounting portion 23. According to this configuration, the enclosure 4 and the electrical connection component 3 are engaged by causing the projection-like portion 31 as the engaging portion 29 to project from the enclosure 4 to the electrical connection component 3. Thus, for example, if the mounting portion 23 has a projecting shape, a projecting amount needs not be increased. This further contributes to the size reduction of the electrical connection component 3.

### Second Embodiment

Next, a second embodiment is described. Note that the shape of the engaging portions 29 of the first embodiment is changed in the second embodiment. Thus, the same components as in the first embodiment are denoted by the same reference signs and not described, and only different parts are described in detail.

### Positioning Structure of Electrical Connection Component 3 and Enclosure 4

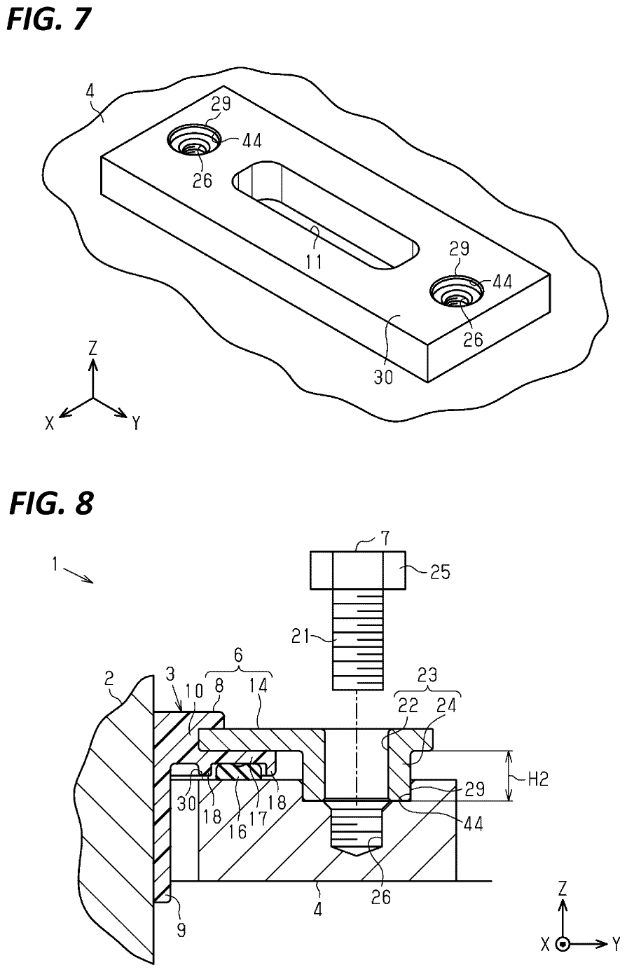

As shown in FIG. 7, an engaging portion 29 includes a recess-like portion 44 recessed from a surface 30 of an enclosure 4. The recess-like portions 44 are provided on both sides in a width direction of the enclosure 4 (Y-axis direction of FIG. 7), whereby a total of two recess-like portions 44 are formed. The recess-like portion 44 is formed as a hole circular in a plan view. A fastened portion 26 is arranged in a center of the recess-like portion 44 in the bottom surface of the recess-like portion 44.

As shown in FIG. 8, the engaging portion 29 positions an electrical connection component 3 and the enclosure 4 by accommodating a mounting portion 23 in the recess-like portion 44. In the case of this example, a projecting wall 24 of the mounting portion 23 is accommodated in the recess-like portion 44, whereby the enclosure 4 and a body portion 6 are positioned. As just described, the projecting wall 24 of the mounting portion 23 is fit into the recess-like portion 44. A height H2 of the projecting wall 24 is set to a value, which is the sum of a thickness of a seal supporting portion 17 supported by a plate portion 14, a thickness of a sealing member 16 resiliently deformed by being pressed by the seal supporting portion 17 and a depth of the recess-like portion 44.

### Positioning of Electrical Connection Component 3 with Respect to Enclosure 4

As shown in FIG. 8, when the electrical connection component 3 is fixed to the enclosure 4, a wiring supporting portion 9 of the electrical connection component 3 is inserted into an opening hole 11 of the enclosure 4 and the projecting walls 24 of the mounting portions 23 formed in the electrical connection component 3 are fit into the recess-like portions 44 of the engaging portions 29 formed in the enclosure 4. Then, shaft portions 21 of fastening portions 7 are inserted into holes 22 of the mounting portions 23 and fastened to the fastened portions 26 in the recess-like portions 44, whereby the electrical connection component 3 is fixed to the enclosure 4.

As just described, when the electrical connection component 3 is fixed to the enclosure 4, the projecting walls 24 of the electrical connection component 3 are fit into the recess-like portions 44 of the enclosure 4, whereby the electrical connection component 3 is positioned with respect to the enclosure 4. Thus, also in the case of this example, the mounting portions 23, through which the fastening portions 7 are passed, are used also to position the electrical connection component 3 and the enclosure 4. Therefore, it is not necessary to provide a positioning portion separately from the mounting portions 23. Hence, the electrical connection component 3 and, consequently, the electrical connection unit 1 can be reduced in size.

### Effects of Second Embodiment

According to the configuration of the second embodiment, the following effect can be obtained in addition to the effects of the above embodiment.
(2.1) The engaging portion 29 includes the recess-like portion 44 recessed from the surface 30 of the enclosure 4, and positions the electrical connection component 3 and the enclosure 4 while the mounting portion 23 is accommodated in the recess-like portion 44. According to this configuration, when the engaging portion 29 is provided in the enclosure 4, it is sufficient to recess a part of the surface 30 of the enclosure 4 by a simple processing. This contributes the simple manufacturing of the enclosure 4.

### Third Embodiment

Next, a third embodiment is described. Note that only parts different from the first and second embodiments are described in detail in the third embodiment.

### Structure of Body Portion 6 of Electrical Connection Component 3

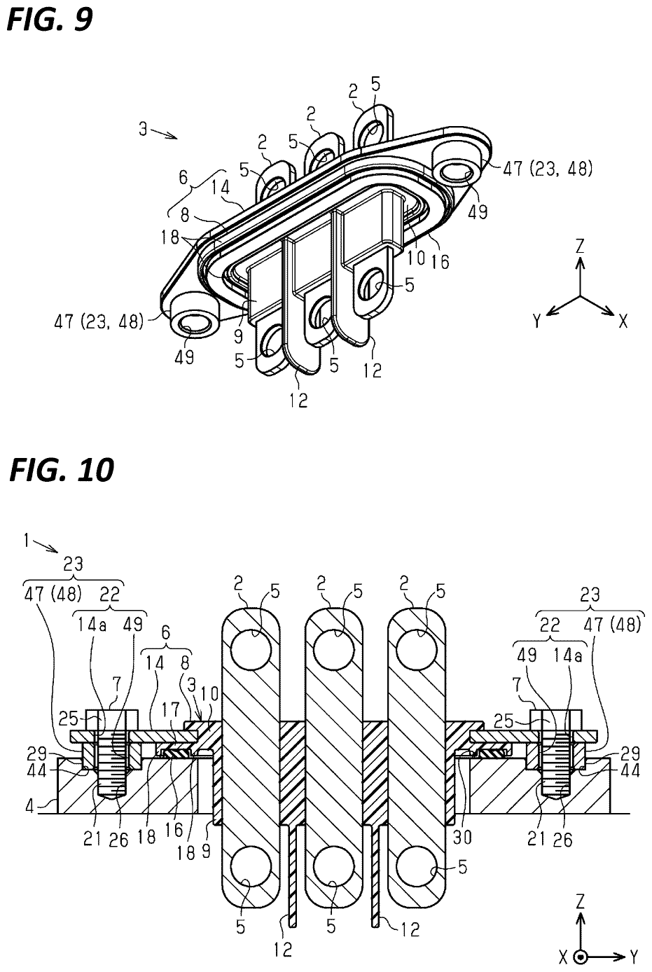

As shown in FIGS. 9 and 10, a mounting portion 23 is configured to include a separate component 47 independent of a body portion 6. As just described, an electrical connection component 3 includes the separate components 47 mounted as the mounting portions 23 in the body portion 6. In the case of this example, the separate component 47 is, for example, a collar 48 retro-fit to a plate portion 14.

As shown in FIG. 10, the plate portion 14 is in the form of a flat plate as a whole. In the case of this example, the plate portion 14 includes plate holes 14a formed by perforating the flat plate-like plate portion 14. The collar 48 is mounted and fixed in this plate hole 14a. In the case of this example, a hole 22, through which a shaft portion 21 of a fastening portion 7 is passed, includes the plate hole 14a and a collar hole 49 of the collar 48. Further, the mounting portion 23 includes the plate hole 14a and the collar 48.

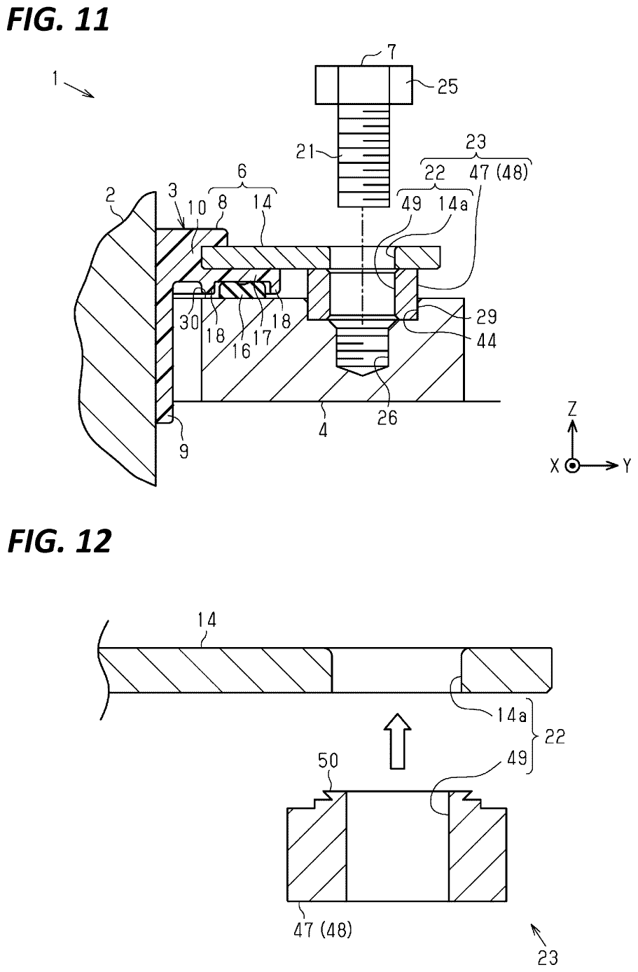

As shown in FIG. 11, the collar 48 is so retro-fit to the plate portion 14 that the plate hole 14a communicates with the collar hole 49. The plate hole 14a and the collar hole 49 are coaxially arranged. The collar hole 49 is so formed that a diameter thereof is equal to that of the plate hole 14a. The inner peripheral surface of the collar hole 49 is formed into a smooth shape without any screw threads. The collar 48 is fit into a recess-like portion 44 of an engaging portion 29.

As shown in FIG. 12, the collar 48 is, for example, preferably a crimp collar to be mounted in the plate hole 14a by crimping. In the case of this example, the collar 48 has an engagement margin 50 for crimping on the peripheral edge of an upper part. The engagement margin 50 is, for example, a projecting piece protruding radially outward by a predetermined amount. The collar 48 is mounted and fixed to the plate portion 14 by crimping the engagement margin 50 to the inner peripheral surface of the plate hole 14a.

### Positioning of Electrical Connection Component 3 with Respect to Enclosure 4

As shown in FIG. 11, when the electrical connection component 3 is fixed to the enclosure 4, the collar 48 of the electrical connection component 3 is fit into the recess-like portion 44 of the enclosure 4, whereby the electrical connection component 3 is positioned with respect to the enclosure 4. Thus, also in the case of this example, the collars 48, through which the fastening portions 7 are passed, are used also to position the electrical connection component 3 and the enclosure 4. Therefore, it is not necessary to provide a positioning portion separately from the collars 48. Hence, the electrical connection component 3 and, consequently, the electrical connection unit 1 can be reduced in size.

### Effects of Third Embodiment

According to the configuration of the third embodiment, the following effects can be obtained in addition to the effects of the above embodiments.
(3.1) At least one of the mounting portions 23 is configured to include the separate component 47 independent of the body portion 6. According to this configuration, manufacturing variations of the mounting portion 23 can be increased using the separate component 47.
(3.2) The separate component 47 is the collar 48 mounted in the plate portion 14 while including the collar hole 49 communicating with the plate hole 14a formed in the plate portion 14. At least one of the mounting portions 23 includes the plate hole 14a and the collar 48. According to this configuration, the mounting portion 23 can be simply formed, using the general-purpose collar 48.

### Fourth Embodiment

Next, a fourth embodiment is described. Note that only parts different from the first to third embodiments are described in detail in the fourth embodiment.

### Structure of Body Portion 6 of Electrical Connection Component 3

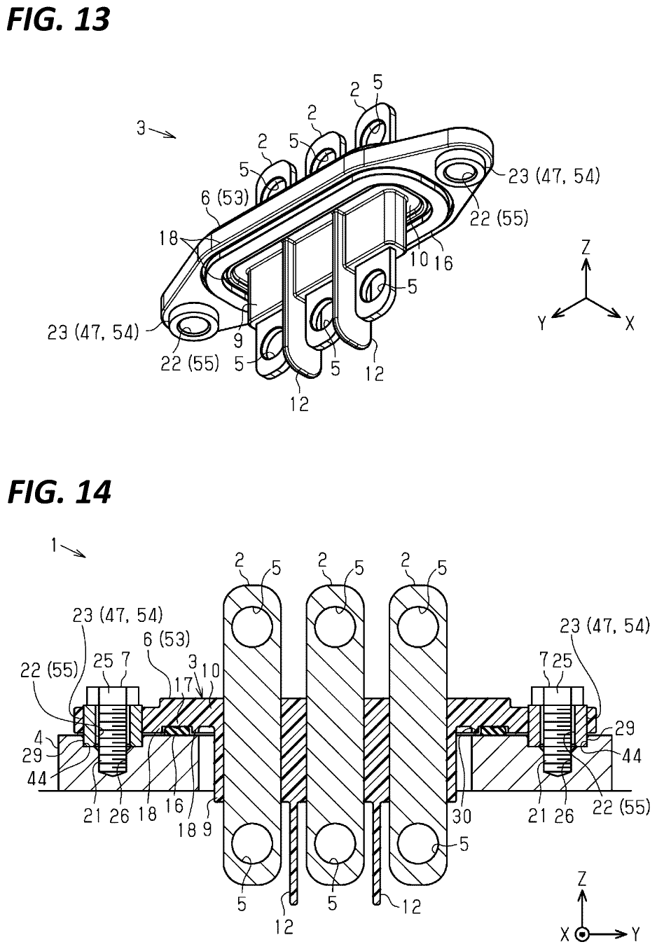

As shown in FIGS. 13 and 14, a body portion 6 is an insulating resin 53 for insulting between a plurality of wirings 2. As just described, a member for supporting the wirings 2 is only one insulating resin 53. The insulating resin 53 is shaped to include a wiring supporting portion 9 for supporting the wirings 2 and a flange portion 10 extending in a direction intersecting the wiring supporting portion 9 and having separate components 47 arranged therein. Various insulating materials such as a phenol resin are, for example, used as a material of the insulating resin 53.

At least one of mounting portions 23 is constituted by an insert collar 54 as a separate component 47 insert-molded in the insulating resin 53. The insert collars 54 are provided on both sides of the insulating resin 53, whereby a total of two insert collars 54 are formed. In the case of this example, an electrical connection component 3, in which the wirings 2 and the insert collars 54 are integrated with the insulating resin 53, is formed by insert molding to fill a resin into a mold having the wirings 2 and the insert collars 54 set therein.

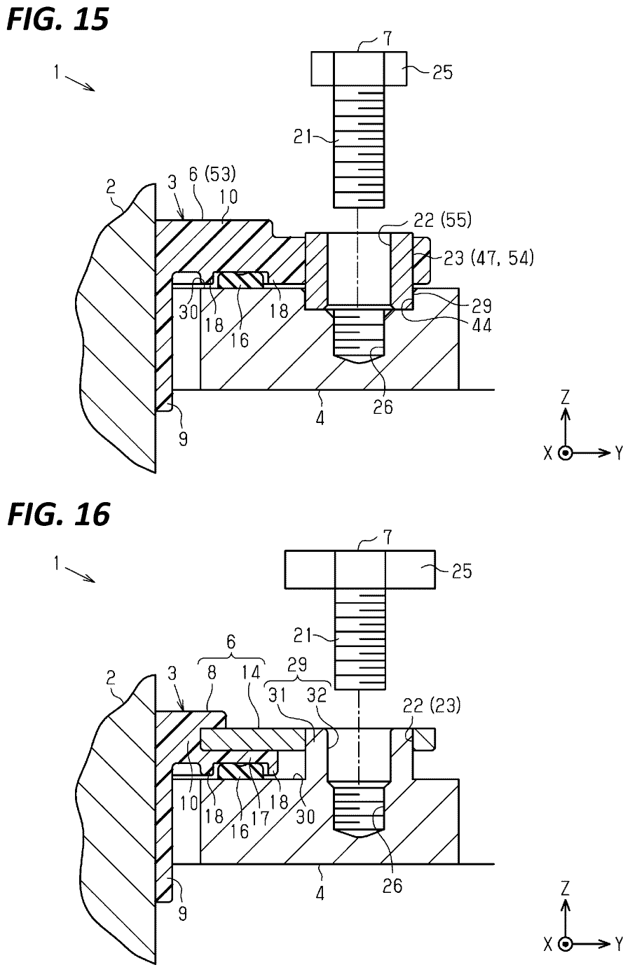

As shown in FIG. 15, the insert collar 54 is provided through the insulating resin 53 in a thickness direction (Z-axis direction of FIG. 15). The insert collar 54 includes a collar hole 55 as a hole 22, through which a shaft portion 21 of a fastening portion 7 is passed. The inner peripheral surface of the collar hole 55 is formed into a smooth shape without any screw threads.

### Positioning of Electrical Connection Component 3 with Respect to Enclosure 4

As shown in FIG. 15, when the electrical connection component 3 is fixed to an enclosure 4, the insert collar 54 of the electrical connection component 3 is fit into a recess-like portion 44 of the enclosure 4, whereby the electrical connection component 3 is positioned with respect to the enclosure 4. Thus, also in the case of this example, the insert collars 54, through which the fastening portions 7 are passed, are used also to position the electrical connection component 3 and the enclosure 4. Therefore, it is not necessary to provide a positioning portion separately from the insert collars 54. Hence, the electrical connection component 3 and, consequently, the electrical connection unit 1 can be reduced in size.

### Effects of Fourth Embodiment

According to the configuration of the fourth embodiment, the following effect can be obtained in addition to the effects of the above embodiments.
(4.1) The body portion 6 is the insulating resin 53 for insulating between the plurality of wirings 2. At least one of the mounting portions 23 is constituted by the insert collar 54 as the separate component 47 insert-molded in the insulating resin 53. According to this configuration, the electrical connection component 3 can be manufactured by a simple method of insert-molding the wirings 2 and the insert collar 54 with the resin.

### Other Embodiment

Note that these embodiments can be modified and carried out as follows. These embodiments and the following modifications can be combined with each other and carried out without technically contradicting.
In the first embodiment, the positioning structure may be, for example, such that the projection-like portions 31 of the enclosure 4 are engaged with the holes 22 provided in the flat plate-like plate portion 14 as shown in FIG. 16. That is, the projecting walls 24 may be omitted from the plate portion 14, and the electrical connection component 3 may be positioned with respect to the enclosure 4 by engaging the projection-like portions 31 of the enclosure 4 with the holes 22 formed in the mounting portions 23. Also by this configuration, the mounting portions 23 can be used also to position the electrical connection component 3 and the enclosure 4.
In the first embodiment, the projection-like portion 31 may be composed of a plurality of projecting pieces arranged at intervals in the circumferential direction.
In the first and second embodiments, the shape of the projecting wall 24 is not limited to the tubular shape and the projecting wall 24 may be, for example, formed as plate pieces intermittently formed in the circumferential direction.
In the first and second embodiments, the drawing process technique can be changed to another technique other than the one in the embodiments as appropriate.
In the first and second embodiments, the plate portion 14 is not limited to the one integrally formed to the insulating portion 8 by insert molding. The plate portion 14 may be, for example, retro-fit to an assembly of the wirings 2 and the insulating portion 8.
In the first to third embodiments, if the plate portion 14 has a rectangular shape, the mounting portions 23 may be formed at four corners. This also applies to the insulating resin 53 of the fourth embodiment.
In the first to third embodiments, screw threads may be formed on the inner peripheral surface of the hole 22 (plate hole 14a) of the mounting portion 23, for example, by tapping.
In the first to third embodiments, the electrical connection component 3 may not be mounted and fixed to the enclosure 4 entirely by the plate portion 14. For example, the electrical connection component 3 may be mounted and fixed to the enclosure 4 partly by the plate portion 14 and partly by the insulating portion 8.
In the third and fourth embodiments, the separate component 47 is not limited to the collar 48 (insert collar 54), but another member may be used.
In each embodiment, the shape of the wiring 2 is not limited to the plate-like shape, but may be a columnar shape. Further, if the wiring 2 has a columnar shape, both ends may be formed into a plate-like shape.
In each embodiment, the shape of the wiring 2 is not limited to a straight shape, but may be bent halfway.
In each embodiment, the arrangement positions and the number of the mounting portions 23 may be changed as appropriate.
In each embodiment, the mounting portion 23 is not limitedly used as a part for fixing the electrical connection component 3 to the enclosure 4. For example, the mounting portion 23 may be used as a part for mounting another component on the electrical connection component 3.
In each embodiment, the arrangement and the number of the mounting portions 23 may be changed as appropriate.
In each embodiment, the fastening portion 7 is not limited to a bolt or a screw, but may be, for example, another member such as a clip.
In each embodiment, the hole 22 may be shaped by cutting a part of a hole peripheral edge.
In each embodiment, a plurality of the mounting portions 23 may respectively have different shapes.
In each embodiment, the electrical connection component 3 is not limited to the terminal block, but may be a connector. In this case, the electrical connection unit 1 is not limited to the terminal block unit, but may be a connector unit.
In the non-limited embodiment shown in FIG. 5, the projecting wall 24 of the plate portion 14 may be referred to as a first spacer projection projecting from the plate portion 14 in a direction intersecting a plane direction (XY plane) of the plate portion 14. The first spacer projection may be a tubular projection. The projecting wall 24 of the plate portion 14 formed by the drawing process shown in FIG. 5 may have a radially inward facing surface (e.g. the inner peripheral surface of the hole 22) continuously and seamlessly spreading from the upper surface of the plate portion 14, a radially outward facing surface (e.g. the outer peripheral surface of the projecting wall 24) continuously and seamlessly spreading from the lower surface of the plate portion 14 and a tip or an opening end surface to be directly supported on or directly held in contact with the surface 30 of the enclosure 4. This first spacer projection may include a bent portion bent, for example, at a right angle (e.g. in the Z-axis direction) to the plane direction (upper surface and lower surfaces) of the plate portion 14. This bent portion of the first spacer projection can have a radially inward facing annular convex curved surface continuously and seamlessly connecting the upper surface of the plate portion 14 and the inner peripheral surface of the hole 22 or the inner peripheral surface of the projecting wall 24 and a radially outward facing annular concave curved surface continuously and seamlessly connecting the lower surface of the plate portion 14 and the outer peripheral surface of the projecting wall 24.
The plate portion 14 in the non-limited embodiment is an example of a plastic material plate.
In the shown non-limited embodiment, the engaging portion 29 formed on the surface 30 of the enclosure 4 may be referred to as a receiving portion configured to be convex-concave engaged with the mounting portion 23 of the plate portion 14 by receiving the projecting wall 24 of the plate portion 14. For example, in the example shown in FIG. 5, the engaging portion 29 of the enclosure 4 can have a radially inward facing side surface and a bottom surface to be respectively brought into contact with the side surface and the tip of the projecting wall 24 (first spacer projection) of the plate portion 14 so that the surface 30 of the enclosure 4 and the lower surface of the plate portion 14 are positioned in a height direction (Z) while the enclosure 4 and the plate portion 14 are positioned in the plane direction (XY plane) of the plate portion 14. In the non-limited embodiment shown in FIG. 5 the projection-like portion 31 of the engaging portion 29 of the enclosure 4 may have a tubular shape and may be referred to as a second spacer projection.
In the non-limited embodiment shown in FIGS. 7, 8, 10 and 11, the recess-like portion 44 of the enclosure 4 can have a radially inward facing side surface and a bottom surface for respectively contacting the side surface and the tip of the projecting wall 24 (first spacer projection) of the plate portion 14 to position the enclosure 4 and the plate portion 14 in the plane direction (XY plane) of the plate portion 14 and position the surface 30 of the enclosure 4 and the lower surface of the plate portion 14 in the height direction (Z).
In the non-limited embodiment shown in FIG. 5, the height H1 of the projecting wall 24 of the plate 14 is a distance from the base end of the projecting wall 24 to the tip of the projecting wall 24 in a direction (Z-axis direction) orthogonal to the plane direction (XY plane) of the plate 14. The same applies also to the height H2 of the projecting wall 24 shown in FIG. 8.
The electrical connection component 3 and the electrical connection unit 1 of the shown non-limited embodiment may be for a vehicle such as an electric vehicle or a hybrid vehicle, similarly to those disclosed in Patent Document 1 (Japanese Unexamined Patent Publication No. 2011-160619).
In each embodiment, the expression “at least one” used in the present disclosure means “one or more” of desired options. As an example, the expression “at least one” used in the present disclosure means “only one option” or “both of two options” if the number of options is two. As another example, the expression “at least one” used in the present disclosure means “only one option” or “a combination of two or more arbitrary options” if the number of options is three or more.
Although the present disclosure has been described with reference to each embodiment, it is understood as not being limited to the embodiments and structures. The present disclosure encompasses various modifications and modifications within the range of equivalents. In addition, various combinations and forms, as well as other combinations and forms including only one element or more or less elements than that are also within the scope and sprit of the present disclosure.

### LIST OF REFERENCE NUMERALS

1 electrical connection unit
2 wiring
3 electrical connection component
4 enclosure
5 insertion hole
6 body portion
7 fastening portion
8 insulating portion
9 wiring supporting portion
10 flange portion
11 opening hole
12 wall portion
14 plate portion
14a plate hole (mounting portion)
16 sealing member
17 seal supporting portion
18 positioning wall
21 shaft portion
22 hole
23 mounting portion (positioning portion, drawn portion)
24 projecting wall
25 head portion
26 fastened portion
29 engaging portion
30 surface
31 projection-like portion
32 recess
34 plate base material
35 drawing machine
36 base portion
37 pressing portion
38 punch
39 opening
40 guide recess
44 recess-like portion
47 separate component
48 collar (mounting portion)
49 collar hole
50 engagement margin
53 insulating resin
54 insert collar (separate component, mounting portion)
55 collar hole
H1 height
H2 height

1. An electrical connection component, comprising:
a plurality of wirings; and
a body portion integrally provided to the plurality of wirings, the body portion being fixed to an enclosure as a mounting destination by fastening portions,
the body portion including mounting portions provided with holes, shaft portions of the fastening portions being passed through the holes,
the plurality of wirings being a plurality of metal flat busbars extending in a height direction of the electrical connection component,
the body portion including an insulating portion for insulating between the plurality of metal flat busbars and a plate portion made of metal, the plate portion being integrally provided to
the insulating portion, the plate portion being fixed to the enclosure by the fastening portions, the insulating portion including a flange portion spreading in a plane direction orthogonal to the height direction of the electrical connection component, the flange portion having a flange upper surface, the flange upper surface being an uppermost surface of the insulating portion located highest in the height direction, and
at least one of the mounting portions doubling as a positioning portion for the enclosure and the body portion provided in the plate portion made of metal and extending outward in the plane direction from the flange portion of the insulating portion.

2. (canceled)

3. The electrical connection component of claim 1, wherein at least one of the mounting portions is integrally formed to the plate portion.

4. The electrical connection component of claim 3, wherein the mounting portion includes a drawn portion having a projecting wall projecting toward the enclosure from a peripheral edge of the hole.

5. The electrical connection component of claim 1, wherein at least one of the mounting portions includes a separate component independent of the body portion.

6. The electrical connection component of claim 5, wherein:
the separate component is a collar to be mounted in the plate portion while including a collar hole communicating with a plate hole formed in the plate portion, and at least one of the mounting portions includes the plate hole and the collar.

7. (canceled)

8. The electrical connection component of claim 1, wherein:
the enclosure includes an engaging portion to be engaged with the mounting portion, and the engaging portion includes a projection-like portion projecting from a surface of the enclosure and positions the electrical connection component and the enclosure while the projection-like portion is engaged with the mounting portion.

9. The electrical connection component of claim 1, wherein:
the enclosure includes an engaging portion to be engaged with the mounting portion, and
the engaging portion includes a recess-like portion recessed from a surface of the enclosure and positions the electrical connection component and the enclosure while the mounting portion is accommodated in the recess-like portion.

10. An electrical connection unit, comprising:
an electrical connection component including a plurality of wirings and a body portion integrally provided to the plurality of wirings; and
an enclosure, the electrical connection component being fixed to the enclosure by fastening portions,
the body portion including mounting portions provided with holes, shaft portions of the fastening portions being passed through the holes,
the plurality of wirings being a plurality of metal flat busbars extending in a height direction of the electrical connection component,
the body portion including an insulating portion for insulating between the plurality of metal flat busbars and a plate portion made of metal, the plate portion being integrally provided to the insulating portion, the plate portion being fixed to the enclosure by the fastening portions,
the insulating portion including a flange portion spreading in a plane direction orthogonal to the height direction of the electrical connection component, the flange portion having a flange upper surface, the flange upper surface being an uppermost surface of the insulating portion located highest in the height direction, and
at least one of the mounting portions doubling as a positioning portion for the enclosure and the body portion provided in the plate portion made of metal and extending outward in the plane direction from the flange portion of the insulating portion.
